(19) United States
(12) Patent Application Publication
(10) Pub. No.: US 2013/0168146 A1
(43) Pub. Date: Jul. 4, 2013

(54) METAL TERMINAL BLOCK ADAPTED FOR SURFACE MOUNTING AND METHOD OF MOUNTING THE SAME

(71) Applicants: JOINSET CO., LTD., Kyeonggi-do (KR); Jin-San KIM, Kyeonggi-do (KR); Seo-Kyung KIM, Kyeonggi-do (KR)

(72) Inventors: Jin-San KIM, Kyeonggi-do (KR); Seo-Kyung KIM, Kyeonggi-do (KR)

(73) Assignees: Jin-San Kim, Kyeonggi-do (KR); JOINSET CO., LTD., Kyeonggi-do (KR); Seo-Kyung KIM, Kyeonggi-do (KR)

(21) Appl. No.: 13/690,853

(22) Filed: Nov. 30, 2012

(30) Foreign Application Priority Data
Dec. 28, 2011 (KR) KR 10-20110145160
Jun. 22, 2012 (KR) KR 10-20120067486

(51) Int. Cl. H05K 1/18

(52) U.S. Cl. CPC H05K 1/181
USPC 174/260; 228/256

(57) ABSTRACT

Provided is a metal terminal block adapted for surface mounting, which includes a metal body having a three-dimensional shape, an outer surface of which includes at least one portion appropriate for vacuum pickup. The metal terminal block provided on a reel carrier through taping is picked up through the vacuum pickup on the portion of the outer surface of the metal body and is mounted on a conductive pattern of a circuit board through the surface mounting. A back surface of the metal terminal block is adhered to the conductive pattern through reflow soldering. The metal body has an insertion recess extending from a surface to an opposite surface thereto, or an insertion hole passing through a surface to an opposite surface thereto.

### FIELD OF THE INVENTION

The present invention relates to a metal terminal block adapted for surface mounting, and more particularly, to a metal terminal block that is adapted for reflow soldering on a conductive pattern of a printed circuit board through surface mounting using vacuum pickup, and that is adapted for soldering with a corresponding metal core wire of a cable or a corresponding metal lead of an electronic device.

### BACKGROUND OF THE INVENTION

A conductive portion of various cables such as a coaxial cable may be electrically connected to a conductive pattern of a printed circuit board. To this end, a metal core wire or metal shield material (hereinafter, referred to as a metal core material) having a circular or tetragonal cross section is exposed out of a sheathe of the cable and is brought into direct contact with the conductive pattern of the printed circuit board, and then, the metal core material and the conductive pattern are soldered using solder.

In addition, a lead wire of an electric device such as a thermistor may be electrically connected to a conductive pattern of a printed circuit board. To this end, a metal lead having a circular or tetragonal cross section is exposed out of the lead wire and is brought into direct contact with the conductive pattern of the printed circuit board, and then, the metal lead and the conductive pattern are soldered using solder.

When a metal core material of a cable or a metal lead of an electronic device is directly soldered to a conductive pattern of a printed circuit board, various issues occur according to the structures of the metal core material, the metal lead, and the printed circuit board.

For example, as the weight and size of terminals such as cellular phones are decreased, the inner structure thereof is complicated and miniaturized, and thus, the diameter of cables used in the terminals is significantly decreased. As a result, it is inconvenient to directly solder metal core materials of small cables to a conductive pattern of a printed circuit board. In particular, when a conductive pattern of a printed circuit board is small, soldering strength between a metal core material and the conductive pattern may be decreased, and contact resistance therebetween may be increased.

In addition, it may be inconvenient to solder a metal core material of a cable to an approximately flat printed circuit board.

Furthermore, when a conductive pattern of a printed circuit board having a small ground area, such as a printed circuit board for a cellular phone, is used as a ground pattern, it is difficult to increase a ground area of a metal core material of a cable soldered to the conductive pattern.

When a coaxial cable is used for accurately transmitting a signal, a metal shield material for electromagnetic interference (EMI) shield, which is just under a sheathe, and a metal core wire, which is in the innermost part of the coaxial cable, should be soldered, respectively, to isolated flat conductive patterns of a printed circuit board, which decreases efficiency of the soldering. In addition, since the isolated flat conductive patterns are adjacent to each other, an electrical short circuit may be formed between the metal shield material and the metal core wire according to a result of the soldering. The distance between the metal shield material and the metal core wire may be increased to prevent such short circuiting. However, a portion of the metal core wire exposed out of the metal shield material is increased, so as to decrease EMI shield effect, thereby decreasing performance of the coaxial cable.

When metal core materials are manually soldered, respectively, to conductive patterns formed on a flexible copper clad laminate (FCCL) as a thin, flat, and flexible printed circuit board, soldering time is insufficient due to material properties of the FCCL, In addition, since mechanical strength of the FCCL is poor, entire soldering strength between the metal core materials and the conductive patterns of the FCCL is also poor. Moreover, since the FCCL is thin, when the metal core materials are moved or bent after being directly soldered to the conductive patterns, a soldered portion may be removed therefrom.

In addition, it may be inconvenient to manually solder metal leads of an electronic device to flat conductive patterns of a printed circuit board in order to electrically separate the metal leads from each other on the flat conductive patterns having a significantly small pitch.

Moreover, via holes are formed the flat conductive patterns in order to securely solder the metal leads to the flat conductive patterns, and then, the metal leads are fitted in the via holes before the soldering. Thus, when a printed circuit board is thin, a portion of metal leads protruding out of an opposite side of a printed circuit board to an insertion side of the metal leads is increased. In this case, the portion of the metal leads protruding out of the opposite side of the printed circuit board should be bent.

A conducting portion of various cables such as a coaxial cable may be electrically connected to a conductive pattern of a printed circuit board. To this end, a metal core wire or metal shield material (hereinafter, referred to as a metal core material) having a circular or tetragonal cross section is exposed out of a sheathe of the cable and is brought into direct contact with the conductive pattern of the printed circuit board, and then, the metal core material and the conductive pattern are soldered using solder.

In addition, a lead wire of an electric device such as a thermistor may be electrically connected to a conductive pattern of a printed circuit board. To this end, a metal lead having a circular or tetragonal cross section is exposed out of the lead wire and is brought into direct contact with the conductive pattern of the printed circuit board, and then, the metal lead and the conductive pattern are soldered using solder.

When a metal core material of a cable or a metal lead of an electronic device is directly soldered to a conductive pattern of a printed circuit board, various issues occur according to the structures of the metal core material, the metal lead, and the printed circuit board.

For example, as the weight and size of terminals such as cellular phones are decreased, the inner structure thereof is complicated and miniaturized, and thus, the diameter of cables used in the terminals is significantly decreased. As a result, it is inconvenient to directly solder metal core materials of small cables to a conductive pattern of a printed circuit board. In particular, when a conductive pattern of a printed circuit board is small, soldering strength between a metal core material and the conductive pattern may be decreased, and contact resistance therebetween may be increased.

In addition, it may be inconvenient to solder a metal core material of a cable to an approximately flat printed circuit board.

Furthermore, when a conductive pattern of a printed circuit board having a small ground area, such as a printed circuit board for a cellular phone, is used as a ground pattern, it is difficult to increase a ground area of a metal core material of a cable soldered to the conductive pattern.

When a coaxial cable is used for accurately transmitting a signal, a metal shield material for electromagnetic interference (EMI) shield, which is just under a sheathe, and a metal core wire, which is in the innermost part of the coaxial cable, should be soldered, respectively, to isolated flat conductive patterns of a printed circuit board, which decreases efficiency of the soldering. In addition, since the isolated flat conductive patterns are adjacent to each other, an electrical short circuit may be formed between the metal shield material and the metal core wire according to a result of the soldering. The distance between the metal shield material and the metal core wire may be increased to prevent such short circuiting. However, a portion of the metal core wire exposed out of the metal shield material is increased, so as to decrease EMI shield effect, thereby decreasing performance of the coaxial cable.

When metal core materials are manually soldered, respectively, to conductive patterns formed on a flexible copper clad laminate (FCCL) as a thin, flat, and flexible printed circuit board, soldering time is insufficient due to material properties of the FCCL, In addition, since mechanical strength of the FCCL is poor, entire soldering strength between the metal core materials and the conductive patterns of the FCCL is also poor. Moreover, since the FCCL is thin, when the metal core materials are moved or bent after being directly soldered to the conductive patterns, a soldered portion may be removed therefrom.

In addition, it may be inconvenient to manually solder metal leads of an electronic device to flat conductive patterns of a printed circuit board in order to electrically separate the metal leads from each other on the flat conductive patterns having a significantly small pitch.

Moreover, via holes are formed the flat conductive patterns in order to securely solder the metal leads to the flat conductive patterns, and then, the metal leads are fitted in the via holes before the soldering. Thus, when a printed circuit board is thin, a portion of metal leads protruding out of an opposite side of a printed circuit board to an insertion side of the metal leads is increased. In this case, the portion of the metal leads protruding out of the opposite side of the printed circuit board should be bent.

### SUMMARY OF THE INVENTION

An object of the present invention is to efficiently solder a metal lead of an electronic device or a metal core material of a cable to a conductive pattern of a printed circuit board.

Another object of the present invention is to efficiently solder metal leads of an electronic device or metal core materials of a cable, respectively, to conductive patterns arrayed at a small pitch on a printed circuit board.

Another object of the present invention is to reliably solder a metal lead of an electronic device or a metal core material of a cable to a predetermined position on a conductive pattern of a printed circuit board.

Another object of the present invention is to increase soldering strength between a metal lead of an electronic device or a metal core material of a cable and a conductive pattern of a printed circuit board.

Another object of the present invention is to efficiently solder a metal lead of an electronic device or a metal core material of a cable to a conductive pattern of a printed circuit board without forming a via hole in the conductive pattern.

Another object of the present invention is to perform a soldering process with a substantially increased ground area, without increasing a width of a conductive pattern of a printed circuit board.

Another object of the present invention is to perform a soldering process to decrease contact resistance between a metal lead of an electronic device or a metal core material of a cable and a conductive pattern of a printed circuit board.

Another object of the present invention is to facilitate soldering and increase physical strength, by increasing the height of a conductive pattern of a printed circuit board.

Another object of the present invention is to efficiently connect an electronic device, an electronic device module, a display unit, or a circuit board to a corresponding conductive pattern formed a flexible printed circuit board.

### BRIEF DESCRIPTION OF THE DRAWINGS

The above objects and other advantages of the present invention will become more apparent by describing in detail preferred embodiments thereof with reference to the attached drawings in which:

FIG. 1 is a perspective view illustrating a metal terminal block according to an embodiment of the present invention;

FIG. 2 is a perspective view illustrating metal terminal blocks mounted on a circuit board according to another embodiment of the present invention, with a cross-sectional view illustrating a thermistor as an electronic device which includes metal leads coupled to the metal terminal blocks;

FIG. 3 is a cross-sectional view illustrating a coaxial cable connected to metal terminal blocks according to another embodiment of the present invention;

FIGS. 4A to 4D are perspective views illustrating various metal terminal blocks according to embodiments of the present invention;

FIG. 5 is a perspective view illustrating a metal terminal block mounted on a circuit board according to another embodiment of the present invention; and

FIGS. 6A and 6B are perspective views illustrating metal terminal blocks mounted on a circuit board according to another embodiment of the present invention.

### DETAILED DESCRIPTION OF THE INVENTION

According to an aspect of the present invention, there is provided a metal terminal block adapted for surface mounting, including a metal body having a three-dimensional shape, an outer surface of which includes at least one portion appropriate for vacuum pickup, wherein the metal terminal block provided on a reel carrier through taping is picked up through the vacuum pickup on the portion of the outer surface of the metal body and is mounted on a conductive pattern of a circuit board through the surface mounting, a back surface of the metal terminal block is adhered to the conductive pattern through reflow soldering, the metal body has an insertion recess extending from a surface to an opposite surface thereto, or an insertion hole passing through a surface to an opposite surface thereto, and a metal core wire of a cable or a metal lead of an electronic device is inserted in the insertion recess or the insertion hole and is fixed thereto through soldering.

The insertion recess may be filled with solder cream.

The metal terminal block may further include an inlet hole extending from an outer surface of the metal body to communicate with the insertion hole such that solder cream is put in the inlet hole.

According to another aspect of the present invention, there is provided a metal terminal block adapted for surface mounting, including a metal body having a three-dimensional shape, an outer surface of which includes at least one portion appropriate for vacuum pickup, wherein the metal terminal block provided on a reel carrier through taping is picked up through the vacuum pickup on the portion of the outer surface of the metal body and is mounted on a conductive pattern of a circuit board through the surface mounting, a back surface of the metal terminal block is adhered to the conductive pattern through reflow soldering, the metal body has a slot having a predetermined depth in an outer surface thereof and extending from a surface to an opposite surface thereto, and a metal core wire of a cable or a metal lead of an electronic device is inserted in the slot and is fixed thereto through soldering.

The slot may be disposed in a portion of the outer surface of the metal body, and an insertion hole may be disposed in the rest of the outer surface of the metal body and reach the opposite surface of the metal body.

According to another aspect of the present invention, there is provided a metal terminal block adapted for surface mounting, including a metal body having a three-dimensional shape, an outer surface of which includes at least one portion appropriate for vacuum pickup, wherein the metal terminal block provided on a reel carrier through taping is picked up through the vacuum pickup on the portion of the outer surface of the metal body and is mounted on a conductive pattern of a circuit board through the surface mounting, a back surface of the metal terminal block is adhered to the conductive pattern through reflow soldering, the metal body is divided into a plurality of portions with insulating layers therebetween, each of the portions of the metal body has an insertion recess extending from a surface to an opposite surface thereto, or an insertion hole passing through a surface to an opposite surface thereto, and a metal core wire of a cable or a metal lead of an electronic device is inserted in the insertion recess or the insertion hole and is fixed thereto through soldering.

According to another aspect of the present invention, there is provided a mounting structure for a printed circuit board, including: a metal terminal block including a metal body having a three-dimensional shape, an outer surface of which includes at least one portion appropriate for vacuum pickup, wherein the metal body has an insertion recess extending from a surface to an opposite surface thereto, or an insertion hole passing through a surface to an opposite surface thereto; and a cable or an electronic device, a metal core wire or a metal lead of which is inserted in the insertion recess or the insertion hole and is soldered thereto, wherein the metal terminal block provided on a reel carrier through taping is mounted on a conductive pattern of the printed circuit board through the vacuum pickup and surface mounting, and is adhered to the conductive pattern through reflow soldering.

According to another aspect of the present invention, there is provided a metal terminal block adapted for surface mounting, including a metal body that is soldered to a conductive land disposed on a flexible circuit board and that has a thin washer shape with a vertical through hole, wherein an outer surface of the metal body includes at least one portion appropriate for vacuum pickup, the metal terminal block provided on a reel carrier through taping is picked up through the vacuum pickup on the portion of the outer surface of the metal body and is mounted on the conductive land of the flexible circuit board through the surface mounting, a back surface of the metal terminal block is adhered to the conductive pattern through reflow soldering, and a metal core wire of a cable or a metal lead of an electronic device is fixed to the outer surface of the metal body through soldering.

According to another aspect of the present invention, there is provided a method of mounting an electronic device on a printed circuit board, including: preparing a metal terminal block including a metal body having a three-dimensional shape, an outer surface of which includes at least one portion appropriate for vacuum pickup, wherein the metal body has an insertion recess extending from a surface to an opposite surface thereto; filling the insertion recess with solder cream; mounting the metal terminal block, filled with the solder cream and provided on a reel carrier through taping, on a conductive pattern of the printed circuit board through the vacuum pickup and surface mounting; inserting a metal core wire of a cable or a metal lead of the electronic device into the solder cream to temporarily fix the metal core wire or the metal lead; and performing a reflow soldering process on the printed circuit board to mount the cable or the electronic device on the metal terminal block while mounting the metal terminal block on the conductive pattern.

### DETAILED DESCRIPTION OF THE PREFERRED EMBODIMENTS

Embodiments of the present invention will be described below in more detail with reference to the accompanying drawings.

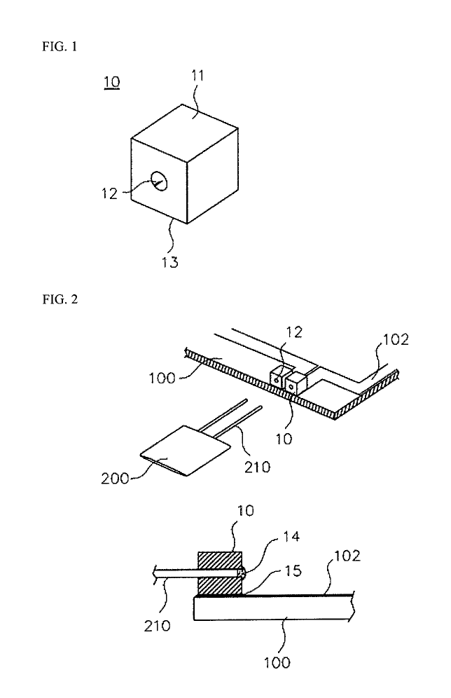

FIG. 1 is a perspective view illustrating a metal terminal block according to an embodiment of the present invention. FIG. 2 is a perspective view illustrating metal terminal blocks mounted on a circuit board according to the current embodiment, with a cross-sectional view illustrating a thermistor as an electronic device which includes metal leads coupled to the metal terminal blocks.

Referring to FIGS. 1 and 2, a metal terminal block 10 has a three-dimensional shape such as a hexahedral shape, and includes an outer surface 11 and a back surface 13 as horizontal surfaces. The metal terminal block 10 is provided in the form of a metal single body. Since the outer surface 11 and the back surface 13 are horizontal, the outer surface 11 is appropriate for surface mounting using vacuum pickup, and the back surface 13 is appropriate for reflow soldering.

An insertion hole 12 passes through a front surface and a back surface, so that a core wire of a cable or a metal lead of an electronic device can be inserted therein, which will be described later. The insertion hole 12 has a circular shape, but is not limited thereto, and thus, may have a tetragonal shape.

For example, the metal terminal block 10 may be formed of one of copper, copper alloy, aluminum, aluminum alloy, nickel, nickel alloy, iron, and iron alloy. For another example, the metal terminal block 10 may be plated with one of stannum, nickel, silver, and gold for preventing oxidation and facilitating reflow soldering.

For another example, the metal terminal block 10 may be fabricated through one of pressing, cutting, and machining.

The size of the metal terminal block 10 is not specifically limited. For example, the height of the metal terminal block 10 may be smaller than the maximum height of electronic devices mounted on a circuit board 100, thereby decreasing the entire volume of a product.

Referring to FIG. 2, the metal terminal block 10 provided on a reel carrier through taping is mounted through surface mounting using vacuum pickup on a conductive pattern 102 of the circuit board 100 with solder cream 15 therebetween, and then undergoes reflow soldering using a reflow machine.

For example, the conductive pattern 102 may have a width greater than that of a back surface of the metal terminal block 10.

As such, metal terminal blocks 10 are soldered to the conductive pattern 102 of the circuit board 100, and metal leads 210 of a thermistor 200 may be inserted in the insertion holes 12 of the metal terminal blocks 10, respectively.

The size of the metal terminal blocks 10 and the diameter of the insertion holes 12 may be varied depending on a pattern width of the conductive pattern 102 or the distance between the metal leads 210.

The metal lead 210 may have a circular or rectangular cross section. The insertion hole 12 may have a cross section corresponding to that of the metal lead 210 and greater than that of the metal lead 210.

Referring to FIG. 2, ends of the metal leads 210 are inserted in the rear ends of the insertion holes 12 without protruding out of the insertion holes 12 in order to increase soldering areas between the ends of the metal leads 210 and the metal terminal blocks 10.

That is, solder 14 contacts large areas on the ends of the metal leads 210 and the metal terminal blocks 10, thereby improving soldering strength.

According to the current embodiment, since a core wire of a cable or a metal lead of an electronic device can be simply inserted into and soldered to a metal terminal block having a predetermined height and pre-soldered to a conductive pattern of a circuit board, installation efficiency is increased and reliable quality is ensured.

In addition, even in the case that a pitch between conductive patterns is small, a terminal block corresponding to the small pitch can be soldered to the conductive pattern. Thus, a soldering process can be performed regardless of the small pitch.

In addition, since a metal terminal block is fixed to a predetermined position, a core wire of a cable or a metal lead of an electronic device can be reliably attached to an accurate position.

In addition, since a core wire of a cable or a metal lead of an electronic device is inserted in an insertion hole of a metal terminal block, mechanical coupling strength between the core wire or the metal lead and the metal terminal block is increased.

In addition, since a metal terminal block protrudes from a conductive pattern formed on a planar circuit board, a soldering process can be efficiently performed without damaging other components.

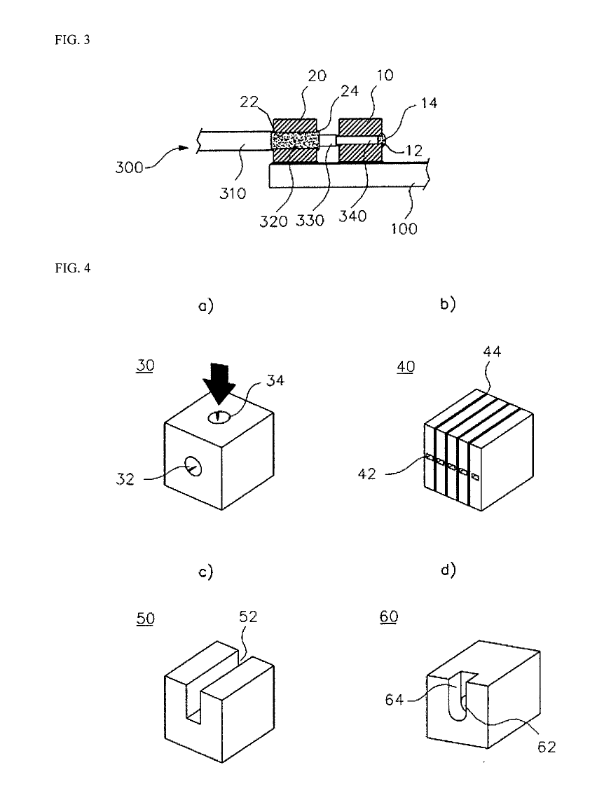

FIG. 3 is a cross-sectional view illustrating a coaxial cable connected to terminal blocks according to an embodiment of the present invention.

According to the current embodiment, a coaxial cable 300 includes a copper core wire 340, an insulating sheath 330, a metal shield material 320, and an insulating sheathe 310, which are sequentially and coaxially disposed from the center of the coaxial cable 300. The copper core wire 340 is inserted in an insertion hole 12 of a metal terminal block 10 and is then soldered, and the metal shield material 320 is inserted in an insertion hole 22 of a metal terminal block 20 and is then soldered.

Since the copper core wire 340 and the metal shield material 320 are different in diameter, the metal terminal blocks 10 and 20 may be different in size.

In particular, the insertion holes 12 and 22 of the metal terminal blocks 10 and 20 may be different in diameter.

As the size of the metal terminal block 20 in which the metal shield material 320 is inserted is increased, electromagnetic interference (EMI) shield performance of the coaxial cable 300 is improved.

The metal shield material 320 formed of a metal may be protruded from both ends of the insertion hole 22 of the metal terminal block 20 such that the metal shield material 320 is soldered to the metal terminal block 20 with solder 24 therebetween.

The coaxial cable 300 is sequentially inserted into the metal terminal block 20 and the metal terminal block 10, and a solder process is performed by forming the solder 24 between the metal shield material 320 and the metal terminal block 20, and solder 14 between the copper core wire 340 and the metal terminal block 10, thereby electrically connecting the metal shield material 320 to the metal terminal block 20, and the copper core wire 340 to the metal terminal block 10. Thus, process simplicity and process efficiency are improved.

Furthermore, since the copper core wire 340 and the metal shield material 320 are reliably protected by the metal terminal blocks 10 and 20, electrical insulation reliability of the copper core wire 340 and the metal shield material 320 can be improved, and the copper core wire 340 and the metal shield material 320 can be fixed to predetermined positions.

In addition, the shape of the metal terminal blocks 10 and 20 or the distance therebetween may be appropriately adjusted to reduce a portion of the copper core wire 340 exposed out of the metal shield material 320, thereby improving EMI shield effect.

FIGS. 4A to 4D are perspective views illustrating metal terminal blocks according to embodiments of the present invention.

Referring to FIG. 4A, a metal terminal block 30 has an insertion hole 32 that passes through the front and rear surfaces thereof to receive a core wire of a cable or a metal lead. An inlet hole 34, through which solder is put in, extends from an outer surface of the metal terminal block 30 to the insertion hole 32.

A core wire of a cable or a metal lead of an electronic device may be inserted into the insertion hole 32, and then, solder may be put in the metal terminal block 30 through the inlet hole 34 to perform a soldering process. Thus, the amount of solder supplied to the metal terminal block 30 can be increased, thereby further increasing soldering strength.

Referring to FIG. 4B, a metal terminal block 40 has an insertion hole 42 that has a tetragonal shape appropriate for receiving a core wire having a tetragonal cross section, such as a flat cable. In particular, when a flat cable includes a plurality of metal core wires that are electrically separated from one another, the metal terminal block 40 may be divided into a plurality of portions with insulating layers 44 therebetween, and insertion holes 42 may be formed in the portions of the metal terminal block 40 to receive the metal core wires.

For example, the metal terminal block 40 and the insulating layers 44 may be fabricated through insert moulding, and the insulating layers 44 may include polymer resin or polymer film.

Referring to FIG. 4C, a metal terminal block 50 may include a slot 52 having a predetermined width in an outer surface thereof.

Solder is formed entirely on a portion of a cable core wire or metal lead inserted in the slot 52, thereby further increasing soldering strength.

Referring to FIG. 4D, a metal terminal block 60 has an insertion hole 62 that includes a slot 64 in a portion thereof, like the slot of FIG. 4C.

A large amount of solder is applied to the slot 64 so as to increase soldering strength, and the insertion hole 62 physically holds a cable core wire or a metal lead of an electronic device.

FIG. 5 is a perspective view illustrating a metal terminal block mounted on a circuit board according to an embodiment of the present invention.

A conductive pattern 102 of a printed circuit board 100 on which electronic devices are mounted includes land portions 104 to which metal terminal blocks 70 are soldered. The land portions 104 have a width greater than that of the conductive pattern 102.

The land portions 104 have no via hole, unlike in the related art. The metal terminal blocks 70 having a cylindrical shape, which replaces a via hole, is provided on the land portions 104 through vacuum pickup and are attached thereto through reflow soldering.

The metal terminal blocks 70 have insertion recesses 72 having a predetermined depth from an outer surface thereof in the height direction thereof. Metal leads 210 of an electronic device 200 are fitted into the insertion recesses 72 and are soldered.

According to another embodiment, the insertion recesses 72 of the metal terminal blocks 70 are filled with solder cream, and then, the metal terminal blocks 70 are provided on a reel carrier through taping. After that, the metal terminal blocks 70 are mounted on a conductive pattern of a circuit board through surface mounting using vacuum pickup, and the metal leads 210 of the electronic device 200 are inserted into the solder cream filling the insertion recesses 72 to temporarily fix the metal leads 210. In this state, when a reflow soldering process is performed, the metal terminal blocks 70 and the conductive pattern undergo reflow soldering, and simultaneously, the metal leads 210 and the solder cream filling the insertion recesses 72 also undergo reflow soldering.

In this case, the entire height of the electronic device 200 and the metal leads 210 is smaller than the maximum height of the other electronic devices mounted on the circuit board.

As such, since metal leads of an electronic device are simply inserted into insertion holes of a metal terminal block and are soldered to be mounted on a circuit board, mounting efficiency is improved.

In addition, since the metal terminal block is fixed to a predetermined position, the metal leads of the electronic device can be reliably attached to an accurate position.

Referring to FIG. 5, the metal terminal blocks 70 may be provided in a pair with a heat resistant insulation body 74 such as heat resistant resin therebetween, and an outer surface of the heat resistant insulation body 74 may be used for vacuum pickup.

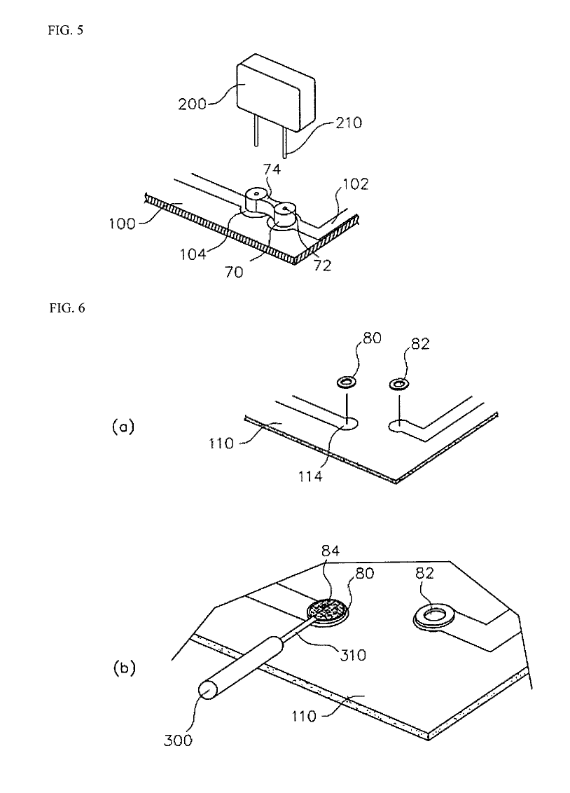

FIGS. 6A and 6B are perspective views illustrating metal terminal blocks mounted on a circuit board according to an embodiment of the present invention.

Metal terminal blocks 80 are formed of a metal and are provided in the form of a thin washer with a hole 82 therein.

Conductive lands 114 to which a cable core wire or a lead of an electronic device is soldered are disposed at ends of a conducive pattern formed on a flexible copper clad laminate (FCCL) 110. The metal terminal blocks 80 are soldered to the conductive lands 114.

The size of the metal terminal blocks 80 may be determined, regardless of the size of the conductive lands 114.

Since the holes 82 are formed in the metal terminal blocks 80, a soldering area of the metal terminal blocks 80 soldered to the conductive lands 114 is increased. The metal terminal blocks 80 are efficiently soldered to the conductive lands 114 by aligning the centers of the metal terminal blocks 80 with the centers of the conductive lands 114.

After the metal terminal block 80 is soldered to the conductive land 114 through surface mounting, a metal lead 310 of a cable 300 or a metal lead of an electronic device, e.g., in a horizontal position, is soldered and fixed to an outer surface of the metal terminal block 80 through solder 84.

Since the metal terminal blocks 80 formed of a metal have higher strength than that of the conductive lands 114, soldering strength of metal leads soldered to the metal terminal blocks 80 is higher than that of metal leads soldered to the conductive lands 114, and thus, the metal leads are securely attached to the metal terminal blocks 80.

Since the holes 82 are formed in the metal terminal blocks 80, a soldering area of the metal terminal blocks 80 and metal leads is increased, thereby increasing soldering strength therebetween. Thus, the metal leads are reliably adhered to the metal terminal blocks 80.

As a result, since sufficient soldering strength between the metal terminal blocks 80 and objects is ensured, even in the case that the objects are moved or bent after soldering, a soldered portion between the metal terminal blocks 80 and the objects is not removed.

Furthermore, the metal terminal blocks 80 may have an area greater than that of the conductive lands 114 to sufficiently increase a space for vacuum pickup, thereby facilitating reflow soldering using the vacuum pickup. Moreover, a slot may be formed along an edge of the metal terminal blocks 80 to increase a soldering area between the metal terminal blocks 80 and the conductive lands 114, thereby ensuring soldering reliability therebetween.

As in the previous embodiments, the metal terminal blocks 80 may be provided on a reel carrier through taping before being supplied, and undergo vacuum pickup and reflow soldering.

Although circular metal terminal blocks are exemplified in the current embodiment, the shape of metal terminal blocks according to the present invention is not specifically limited.

According to the embodiments, since a metal core material of a cable or a metal lead of an electronic device can be simply inserted into and soldered to a metal terminal block that has a predetermined height on a conductive pattern of a printed circuit board through surface mounting and that is pre-soldered to the conductive pattern through reflow soldering, soldering efficiency and soldering strength are increased and electrical contact resistance is decreased.

In addition, even in the case that a pitch between conductive patterns is small, a metal terminal block corresponding to the small pitch can be soldered to the conductive pattern. Thus, a soldering process can be performed regardless of the small pitch.

In addition, since a metal terminal block is fixed to a predetermined position, a cable core wire or a metal lead of an electronic device can be reliably attached to an accurate position.

In addition, since a metal terminal block is mounted on a conductive pattern, a ground area is entirely increased.

In addition, a via hole of a conductive pattern is replaced with a metal terminal block, an additional process cost can be saved.

In addition, the amount of solder to be used in a soldering process can be adjusted depending on the structure of a metal terminal block, and a constant amount of solder can be used.

In addition, a metal terminal block is configured to increase mechanical coupling force between the metal terminal block and a cable core wire or a metal lead of an electronic device.

In addition, since an insertion recess of a metal terminal block is filled with solder cream in advance, soldering can be further facilitated.

While the present invention has been described in detail, it should be understood that various changes, substitutions and alterations can be made hereto without departing from the spirit and scope of the invention as defined by the appended claims.

What is claimed is:

1. A metal terminal block adapted for surface mounting, comprising a metal body having a three-dimensional shape, an outer surface of which comprises at least one portion appropriate for vacuum pickup,
wherein the metal terminal block provided on a reel carrier through taping is picked up through the vacuum pickup on the portion of the outer surface of the metal body and is mounted on a conductive pattern of a circuit board through the surface mounting,
a back surface of the metal terminal block is adhered to the conductive pattern through reflow soldering,
the metal body has an insertion recess extending from a surface to an opposite surface thereto, or an insertion hole passing through a surface to an opposite surface thereto, and
a metal core wire of a cable or a metal lead of an electronic device is inserted in the insertion recess or the insertion hole and is fixed thereto through soldering.

2. The metal terminal block of claim 1, wherein the insertion recess is filled with solder cream.

3. The metal terminal block of claim 1, further comprising an inlet hole extending from an outer surface of the metal body to communicate with the insertion hole such that solder cream is put in the inlet hole.

4. A metal terminal block adapted for surface mounting, comprising a metal body having a three-dimensional shape, an outer surface of which comprises at least one portion appropriate for vacuum pickup,
wherein the metal terminal block provided on a reel carrier through taping is picked up through the vacuum pickup on the portion of the outer surface of the metal body and is mounted on a conductive pattern of a circuit board through the surface mounting,
a back surface of the metal terminal block is adhered to the conductive pattern through reflow soldering,
the metal body has a slot having a predetermined depth in an outer surface thereof and extending from a surface to an opposite surface thereto, and
a metal core wire of a cable or a metal lead of an electronic device is inserted in the slot and is fixed thereto through soldering.

5. The metal terminal block of claim 4, wherein the slot is disposed in a portion of the outer surface of the metal body, and
an insertion hole is disposed in the rest of the outer surface of the metal body and reaches the opposite surface of the metal body.

6. A metal terminal block adapted for surface mounting, comprising a metal body having a three-dimensional shape, an outer surface of which comprises at least one portion appropriate for vacuum pickup,
wherein the metal terminal block provided on a reel carrier through taping is picked up through the vacuum pickup on the portion of the outer surface of the metal body and is mounted on a conductive pattern of a circuit board through the surface mounting,
a back surface of the metal terminal block is adhered to the conductive pattern through reflow soldering,
the metal body is divided into a plurality of portions with insulating layers therebetween,
each of the portions of the metal body has an insertion recess extending from a surface to an opposite surface thereto, or an insertion hole passing through a surface to an opposite surface thereto, and
a metal core wire of a cable or a metal lead of an electronic device is inserted in the insertion recess or the insertion hole and is fixed thereto through soldering.

7. A mounting structure for a printed circuit board, comprising:
a metal terminal block comprising a metal body having a three-dimensional shape, an outer surface of which comprises at least one portion appropriate for vacuum pickup, wherein the metal body has an insertion recess extending from a surface to an opposite surface thereto, or an insertion hole passing through a surface to an opposite surface thereto; and
a cable or an electronic device, a metal core wire or a metal lead of which is inserted in the insertion recess or the insertion hole and is soldered thereto,
wherein the metal terminal block provided on a reel carrier through taping is mounted on a conductive pattern of the printed circuit board through the vacuum pickup and surface mounting, and is adhered to the conductive pattern through reflow soldering.

8. A metal terminal block adapted for surface mounting, comprising a metal body that is soldered to a conductive land disposed on a flexible circuit board and that has a thin washer shape with a vertical through hole,
wherein an outer surface of the metal body comprises at least one portion appropriate for vacuum pickup,
the metal terminal block provided on a reel carrier through taping is picked up through the vacuum pickup on the portion of the outer surface of the metal body and is mounted on the conductive land of the flexible circuit board through the surface mounting,
a back surface of the metal terminal block is adhered to the conductive pattern through reflow soldering, and
a metal core wire of a cable or a metal lead of an electronic device is fixed to the outer surface of the metal body through soldering.

9. A method of mounting an electronic device on a printed circuit board, comprising:
preparing a metal terminal block comprising a metal body having a three-dimensional shape, an outer surface of which comprises at least one portion appropriate for vacuum pickup, wherein the metal body has an insertion recess extending from a surface to an opposite surface thereto;
filling the insertion recess with solder cream;
mounting the metal terminal block, filled with the solder cream and provided on a reel carrier through taping, on a conductive pattern of the printed circuit board through the vacuum pickup and surface mounting;
inserting a metal core wire of a cable or a metal lead of the electronic device into the solder cream to temporarily fix the metal core wire or the metal lead; and
performing a reflow soldering process on the printed circuit board to mount the cable or the electronic device on the metal terminal block while mounting the metal terminal block on the conductive pattern.
